(19) United States
(12) Patent Application Publication
(10) Pub. No.: US 2001/0009280 A1
(43) Pub. Date: Jul. 26, 2001

(54) Organic electroluminescence display device

(75) Inventors: Taizou Tanaka, Tokyo (JP); Kenji Takata, Tokyo (JP)

Correspondence Address: HAYES, SOLOWAY, HENNESSEY,, GROSSMAN & HAGE, P.C., 175 CANAL STREET, MANCHESTER, NH, 03101-2335, US

(73) Assignee: NEC CORPORATION

(21) Appl. No.: 09/765,900

(22) Filed: Jan. 18, 2001

(30) Foreign Application Priority Data
Jan. 21, 2000 (JP) 13431/2000

(51) Int. Cl. H01L 29/04; H01L 27/148; H01L 31/036; H01L 31/0376

(52) U.S. Cl. 257/59; 257/72; 257/231

(57) ABSTRACT

In an organic electroluminescence display device having organic EL elements stacked on a substrate having a plurality of thin-film transistors formed on it, a plurality of pixel electrodes each being electrically connected to either one of the source region and the drain region of each of the thin-film transistors are provided on a flattening layer, and an electron injection layer of an electric insulator such as lithium fluoride is formed commonly on the plurality of pixel electrodes. And an organic layer including a light-emission layer and a hole injection layer are formed on this electron injection layer.

### BACKGROUND OF THE INVENTION

1. Field of the Invention

The present invention relates to an organic electroluminescence (EL) display device, and more particularly to an active organic EL display device provided with a thin-film transistor array substrate.

2. Description of the Prior Art

An organic EL element utilizes a phenomenon in which holes injected from an anode and electrons injected from a cathode are recombined in a light-emission layer having a luminescence capability and light is emitted when they are deactivated from an excited state.

The organic EL element started from application as a monochrome flat light emission source at its early stage of development and in recent years, is greatly expected as a light-emission type full-color display device of an active-driving type which drives organic EL elements corresponding to a plurality of pixels independently of each other by means of switching elements such as thin-film transistors (TFT), namely, as a hopeful display device competitive with a color liquid crystal display device.

An example of such an organic EL display device is disclosed in Japanese Patent Laid-Open Publication No.Hei 11-251,069. This display device has a structure in which organic EL elements are stacked on an insulating leveling layer formed on a TFT layer. Electron injection electrodes formed all over the leveling layer are electrically connected to electrodes of the TFTs through the respective through holes formed in the leveling layer. Thanks to such a structure, a light-emission display can be observed from the opposite side to the substrate.

The structure in which a display can be observed from the opposite side to a substrate on which TFTs are formed has an advantage of improving the aperture efficiency of a display pixel. Material having a small work function is selected for an electron injection electrode. Particularly, MgAg or the like having a smaller work function than 4 eV is known. The same publication discloses that an electron injection electrode is made of a magnesium-indium alloy (MgIn), an aluminum-lithium alloy (AlLi) or the like. Although described as an alloy, a film formed by using a general film forming method such as evaporation or the like is actually not an alloy but a simple mixture layer.

Therefore, there is a problem that since Li, Ag or the like is small in atom size, its atoms diffuse in a leveling layer during or after the formation of the film and greatly deteriorates the characteristics of TFT.

On the other hand, it is very difficult to perform a pattering process for separation of pixels on a layer containing alkali metal such as Li or the like by etching or the like after forming the layer, and although such a process is not said to be impossible, a patterning technique established for Al electrodes and the like cannot be used and therefore it cannot be avoided that the manufacturing cost is greatly increased. Thus, it is the present situation that for patterning such electron injection electrodes containing Li, a film is formed only on the area on which the film is to be formed by using a mask at the time of forming the film.

Accordingly, the above-mentioned patent publication illustrates only an example in which an electron injection electrode is formed on an insulating layer formed on a single TFT, and even if electron injection electrodes are formed also on the TFTs adjacent to each other, it is a matter of course that they are selectively formed when forming the film.

And an accurate mask is required for separation of pixels and electrical connection to TFTs, but a pattern is blurred due to the thickness of a mask or fine parts of a pattern are blurred due to the limitation of creating a fine pattern. Further, there is a problem that since a pattern is blurred due to the flexion of a mask caused by its own weight a film of the cathode material is formed also on an area not intended and this may cause a short circuit.

### SUMMARY OF THE INVENTION

Therefore, an object of the present invention is to provide an organic EL display device of an active matrix driving type containing thin-film transistors of a structure taking light emitted from the opposite side to the TFT substrate, said device using no mask and suppressing the diffusion of a cathode material for an organic EL element.

The present invention provides an organic electroluminescence display device comprising a plurality of thin-film transistors formed on a substrate, a plurality of pixel electrodes each being electrically connected to one of the source region or drain region of each of the thin-film transistors, an electrically insulating electron injection layer formed commonly on the plurality of pixel electrodes, an organic layer including a light-emission layer formed on the electron injection layer, and a hole injection layer formed on the organic layer.

Particularly, in case that the electron injection layer is made of an oxide of alkali metal or an oxide of alkaline-earth metal, it is preferable that the oxide of alkali metal is lithium oxide.

And in case that the electron injection layer is made of a fluoride of alkali metal or a fluoride of alkaline-earth metal, it is preferable that the fluoride of alkali metal is lithium fluoride and the fluoride of alkaline-earth metal is samarium fluoride or magnesium fluoride.

And in the above display device, it is preferable that the electron injection layer is formed to a thickness of 0.5 to 10 nm.

Furthermore, in the above display device, the above organic layer contains at least an electron transport layer and the electron transport layer is made of a quinoline-based complex.

### BRIEF DESCRIPTION OF THE DRAWINGS

FIG. 1 is a cross-sectional view of a schematic structure showing an organic EL display device according to an embodiment of the present invention.

FIG. 2 is a magnified cross-sectional view showing details of a pixel area of FIG. 1.

FIG. 3 is a circuit diagram for explaining how to drive an organic EL display device of an active matrix type of the present invention.

### DETAILED DESCRIPTION OF THE PREFERRED EMBODIMENTS

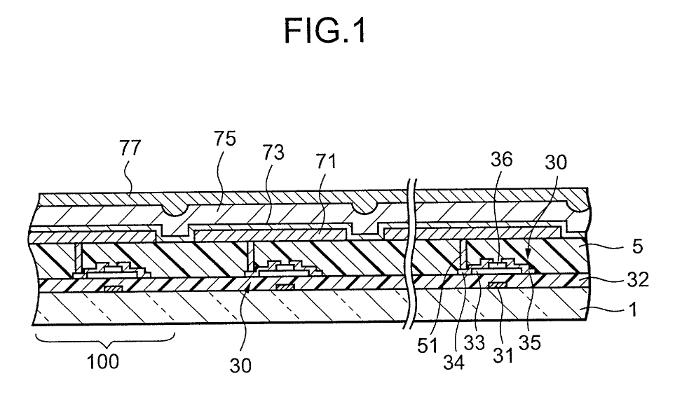

Referring to FIG. 1, a plurality of TFTs 30 is formed on a substrate 1 of glass or the like to provide a plurality of pixel areas 100, and each TFT is covered with a common leveling layer 5. A plurality of pixel electrodes 71 is formed in specific areas on the leveling layer 5. Each pixel electrode 71, respectively, is electrically connected to either of the source region 34 and the drain region 35 of each TFT 30 through a contact through hole 51 formed in the leveling layer 5. In FIG. 1, reference numerals 33 and 36 indicate a semiconductor layer and stopper layer, respectively.

The present invention adopts as an electron injection electrode an electron injection material such as lithium fluoride (LiF) or the like being excellent in ability of insulation. Since such an insulating electron injection electrode 73 can be formed not only on a pixel electrode 71 but also extensively and commonly between adjacent pixel electrodes, a mask in forming a film becomes unnecessary. After that, an organic layer 75 including a light-emission layer is formed all over the electron injection electrode 73, and a hole injection electrode 77 is formed on the top.

And since LiF is a stable compound, Li atoms do not diffuse in the leveling layer differently from a conventional AlLi mixture layer.

A fact that lithium fluoride can be used as an electron injection electrode of an organic EL element although it is insulative is disclosed in Japanese Patent Laid-Open Publication No.Hei 10-74,586. The same publication describes that lithium fluoride is an excellent insulator but a very thin film of lithium fluoride backed with a proper metal layer is an efficient electron injector.

However, the same publication discloses only that LiF can be adopted as an efficient electron injection electrode, but does not disclose nor suggest a structure in which organic EL elements are stacked on a TFT substrate being an object of the present invention. Further, it does not suggest also a structure in which an LiF film is formed commonly over a plurality of pixel electrodes.

Since the present invention can use a patterning technique already industrially established for a pixel electrode film of Al or the like in a range of display pixel area, it can determine a high-definition pattern and does not make the blur of a pattern caused by using a mask differently from the prior art.

An insulating electron injection electrode 73 film of LiF or the like is formed commonly on a plurality of pixel electrodes 71 accurately patterned in such a manner. After this, an organic layer including a light-emission layer is formed all over an electron injection electrode 113, and a hole injection electrode 118 film is formed on the top.

As an example of an organic layer 75 shown in FIG. 1, there is a three-layer structure composed of an electron transport layer, a light-emission layer and a hole transport layer formed in order on an electron injection electrode 73.

As shown in the figure, an electron injection electrode in the present invention is formed commonly over a plurality of pixel electrodes, but the area which functions as an electron injection electrode is limited to an area backed with a pixel electrode. Since an area existing extensively between adjacent pixel electrodes is not backed with metal and functions as an excellent insulator, a pixel separation is sufficiently attained.

A substrate 1 used in the present invention may be an insulating substrate made of glass, plastic or the like, or a conductive substrate having an insulating film such as an SiO₂ film, an SiNₓ film or the like formed on its surface. Or it may use a semiconductor substrate, and TFTs and organic EL elements may be stacked and formed directly on a semiconductor substrate. And in the present invention, the substrate 1 may be either transparent or opaque.

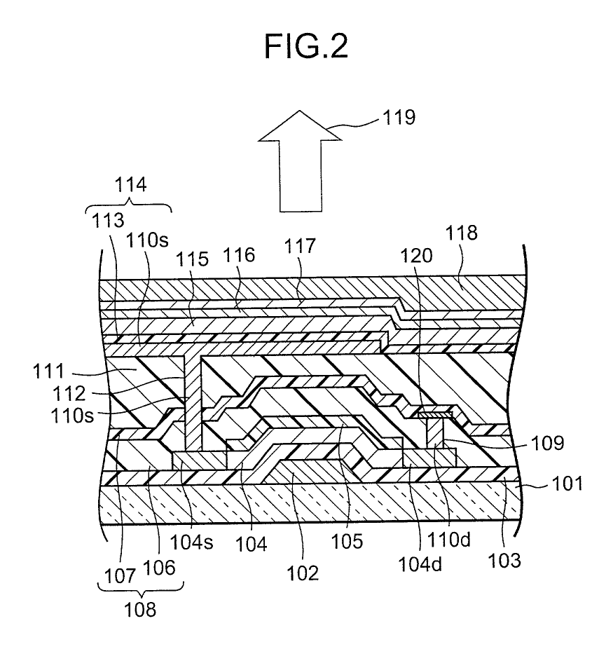

And a structure of TFT formed on the substrate 1 can be formed by a conventional technique publicly known. Referring to FIG. 2 being a magnified view of details of a portion corresponding to one pixel area in FIG. 1, a structure according to the present invention is described in more detail.

As an example, as shown in FIG. 2, an opaque metal layer composed of a high-melting point metal such as Cr, Mo or the like is formed on a substrate 101 by a sputtering method or the like, and is patterned by a method such as photolithography or the like and thereby a gate electrode 102 is formed.

Next, an insulating material of silicon nitride or the like is stacked by a plasma CVD method or the like all over the surface of the substrate including the gate electrode 102 to form a gate insulating film 103.

Furthermore, an active layer 104 of polysilicon (abbreviation of polycrystalline silicon: hereinafter, referred to as p-Si for short) is formed, on which a stopper layer 105 composed of an SiO₂ film is formed.

And a source region 104s and a drain region 104d are formed by implanting n-type or p-type ions into a p-Si film being an active layer 104 using this stopper layer 105 as a mask.

Furthermore, a silicon oxide film (SiO₂ film) 106 is formed all over the top of it as the first interlayer insulating film. Contact holes 112 and 109 leading to the source region and drain region of TFT are formed in the SiO₂ film 106, and a source electrode 110s and a drain electrode 110d are formed, and a drain wiring 120 is formed by patterning. Further, a silicon nitride film (SiNₓ film) is formed as the second interlayer insulating film all over the surface.

A p-Si TFT film for an organic EL device can be formed through such a process.

In this case, the active layer 104 is not limited to p-Si, but may be made of amorphous silicon, microcrystalline silicon or the like. And in addition to a TFT element of a bottom-gate type having a gate electrode provided on the substrate side, a TFT element of a top-gate type structure having an active layer provided on the substrate side and having a gate electrode stacked on the active layer can be also adopted.

Next, a process of forming an organic EL element on TFT is described. A leveling layer 111 is formed on the electrode 110s and 110d of the above-mentioned p-Si TFT and on the interlayer insulating film 108. Material for this leveling layer 111 can be selected from a silicon oxide film, silicon nitride film, a silicate glass film, a plastic film (polyamide-based resin film, organic silica film, acrylic-based resin film and the like). A contact hole 112 is formed in the leveling layer 111.

Next, a pixel electrode 110s is formed by patterning a metal material of aluminum or the like on and around the contact hole 112, and an insulating electron injection layer 113 of lithium fluoride, samarium fluoride, magnesium fluoride, lithium oxide or the like is formed to a thickness of 0.5 to 10 nm on the leveling layer 111 including the pixel electrode 110s without using a mask. As a film forming means, a resistance heating method, an electron beam evaporation method and the like can be mentioned.

Here, material for a pixel electrode and an insulating electron injection layer 113 are generically called a cathode 114 for an organic EL element. An electron transport material of a quinoline-based complex or the like is formed to a thickness of 10 to 100 nm on this cathode 114 by a vacuum evaporation method or the like to form an electron transport layer 115.

Next, a light-emission layer 116 is formed to a thickness of 10 to 100 nm by a method similar to the above technique. As material for a light-emission layer, there can be mentioned naphthoquinacridon derivatives, phthalocyanine derivatives, tetra-azaphthalocyanine bis-styril benzene, bis-styril pyradine derivatives, P-phenylene compound, pyrolopylidine derivatives, silol compound, coumarin derivatives, aluminum complex of 8-hydroxyquinoline and the like. And another material may be doped into these materials being a host material. This doping is done for the purpose of improving the efficiency of light emission of an organic EL element and lengthening the light-emission life of it when it is driven, and a material to be doped is selected from coumarin-based laser dyes, quinacridon derivatives, naphthacene derivatives, perilene derivatives and the like.

Next, a hole transport layer 117 is formed to a thickness of 10 to 100 nm by the above-mentioned technique. As such a hole transport material, there can be mentioned, for example, an aromatic diamine compound in which 3-class aromatic amine units such as 1, 1-bis(4-ditolyl aminophenyl) cyclohexane and the like are linked; aromatic amine which contains two or more 3-class amines, has nitrogen atoms substituted for two or more fused aromatic rings and is represented by 4, 4′-bis(N-(1-naphthyl)-N-phenylamino) biphenyl; aromatic triamine being a derivative of triphenyl benzene and having a star-burst structure (U.S. Pat. No. 4,923,774); aromatic diamine such as N, N′-diphenyl-N or N′-bis(3-methylphenyl) biphenyl-4 or 4′-diamine or the like (U.S. Pat. No. 4,764,625); α, α, α′, α′-tetramethyl-α, α′-bis(4-di-p-tolylaminophenyl)-p-xylene; triphenylamine derivative being three-dimensionally asymmetric on the whole molecule; a compound having pyrenyl groups substituted for plural aromatic diamine groups; aromatic diamine having 3-class aromatic amine units linked by ethylene groups; a compound having 3-class aromatic amine units linked by thiophene groups; aromatic triamine of a star-burst type; a benzylphenyl compound; a compound having 3-class amine units linked by fluorene groups; a triamine compound; bisdipyridyl aminobiphenyl; N, N, N-triphenylamine derivative; aromatic diamine having a phenoxadine structure; diaminophenyl phenantolidine derivative; a hydrazone compound; a silazane compound (U.S. Pat. No. 4,950,950); silanamine derivative; phosphamine derivative; a quinacridon compound; and the like. These compounds may be used independently and may be mixed with one another according to need.

And additionally to the above-mentioned materials, as a material for a hole transport layer 117, there can be mentioned polyvinyl carbazole; polysilane; polyphosphozene; polyamide; polyvinyl triphenyl amine; polymer having a triphenyl amine skeleton; polymer having triphenyl amine units linked by methylene groups and the like; and polymer such as polymethacrylate and the like containing aromatic amine.

Next, a hole injection electrode 118 is formed. The hole injection electrode 118 has preferably a large work function as its desired performance in order to efficiently implant holes into the hole transport layer 117 of an organic EL element. Concretely, the work function is preferably 4 eV or more, and a material for the hole injection electrode 118 is selected from a metal material such as Au, Pt, Pd or the like and a metal oxide such as ITO, IZO (indium or zinc oxide) and the like.

In order to take out the light emitted from an organic EL element, these materials are required to be transparent or translucent, and a film of ITO or IZO is preferably 1 μm or less in thickness and a metal film is preferably 60 nm or less in thickness. And as a film forming method for these materials there can be mentioned a resistance heating evaporation method, an electron beam evaporation method, a sputtering method, a CVD method and the like.

As the structure of an organic EL element, in addition to the above-mentioned structures, the following structures can be mentioned. It is assumed that the left side layer is upper than the right side layer.

(1) Anode/Light-emission layer/Electron injection layer/Metal layer;

(2) Anode/Hole transport layer/Light-emission layer/Electron injection layer/Metal layer;

(3) Anode/Hole injection layer/Light-emission layer/Electron injection layer/Metal layer;

(4) Anode/Hole injection layer/Hole transport layer/Light-emission layer/Electron injection layer/Metal layer;

(5) Anode/Light-emission layer/Electron transport layer/Electron injection layer/Metal layer;

(6) Anode/Hole injection layer/Light-emission layer/Electron transport layer/Electron injection layer/Metal layer;

(7) Anode/Hole injection layer/Hole transport layer/Light-emission layer/Electron transport layer/Electron injection layer/Metal layer.

As a method for driving an organic EL display device of an active matrix driving type stacked on a TFT substrate as described above, it is possible to follow a method for driving a liquid crystal display device. That is, there can be mentioned a passive (matrix) driving method depending on the multiplexing performance of an organic EL display element and an active matrix driving method for driving a switching element such as a thin-film transistor (TFT) or the like attached to each pixel.

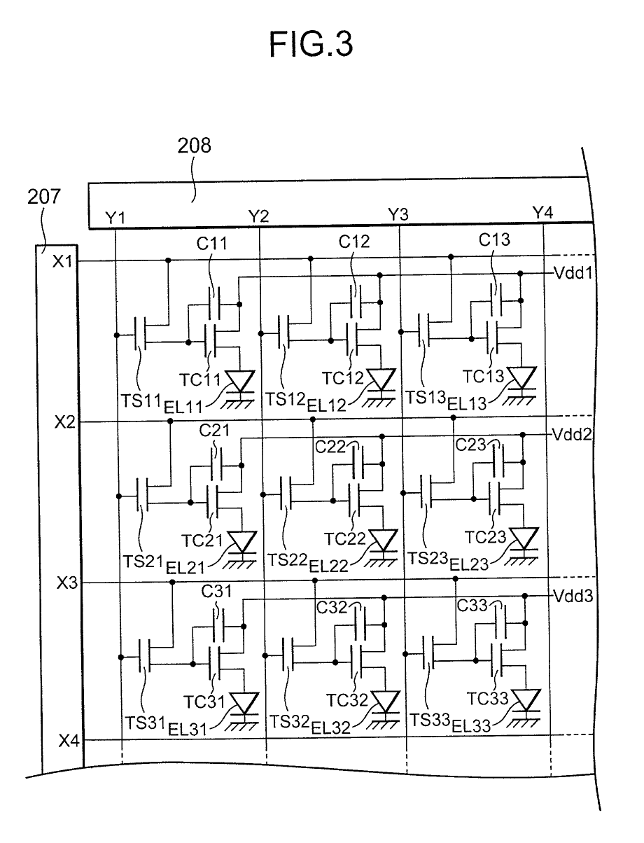

For reference, a circuit for driving an organic EL display device of an active matrix type is described with reference to FIG. 3.

The organic EL display device is composed of X-direction signal lines X1, X2, X3, . . . , Xn, Y-direction signal lines Y1, Y2, Y3, . . . , Ym, power supply (Vdd) lines Vdd1, Vdd2, Vdd3, . . . , Vdd1, thin-film transistors (TFTs) for switching TS11, TS21, TS31, . . . , TS12, TS22, TS23, . . . , TS31, TS32, TS33, . . . , TSnm, thin-film transistors (TFTs) for current control TC11, TC21, TC31, . . . , TC12, TC22, TC23, TC31, TC32, TC33, . . . , TCnm, organic EL elements EL11, EL21, EL31, . . . , EL12, EL22, EL23, . . . , EL31, EL32, EL33, . . . , ELnm, capacitors C11, C21, C31, . . . , C12, C22, C23, . . . , C31, C32, C33, . . . , Cnm, X-direction driving circuit 207, Y-direction driving circuit 208, and the like. Hereupon, only one pixel is selected by one of X-direction signal lines X1 to Xn and one of Y-direction signal lines Y1 to Ym, and a thin-film transistor for switching TS comes into the “on” state at this pixel, and due to this, a thin-film transistor for current control TC comes into the “on” state. Thus, an electric current supplied from a power supply line Vdd flows in the organic EL pixel, which results in emitting light.

In the above, the structure and materials of an organic EL display device containing TFTs have been described, and the TFTs and organic EL elements are more concretely described separately from each other with respect to their manufacturing method.

TFT manufacturing process

An aluminum (Al) film of 150 nm in thickness was formed by a resistance heating evaporation process on a cleaned non-alkali glass (No.1737 manufactured by Corning, Inc.) substrate, and then a gold (Au) film of 10 nm in thickness was deposited on the resulting substrate by means of the same technique. This was patterned by photolithography and wet-etching for a gate electrode.

On the gate electrode, a gate insulating film of silicon nitride was formed to become 200 nm in thickness by means of a plasma CVD method.

Furthermore, a p-Si film was formed on it to be 60 nm in thickness, and then a SiO₂ film was patterned into a specified shape as a stopper. Using this SiO₂ film as a mask, phosphorus (P) was ion-implanted to form a source region and a drain region.

And a SiO₂ film was deposited again, and then SiNₓ was evaporated to form an interlayer insulating film of a 2-layer structure. Next, the interlayer insulating film was etched so that the upper portions of the source and drain regions were opened, and aluminum was evaporated on the whole surface including the openings, and then the aluminum except the aluminum part being on and around the openings was etched away.

Next, the whole surface was coated with a polyamide film by a spin coating method, and thereafter the upper parts of the aluminum film on and around said openings were opened. Following this, after aluminum was evaporated all over the surface, the aluminum film formed outside said openings was removed by a mechano-chemical polishing method and the like.

Organic EL element manufacturing process

A TFT substrate made in such a manner was set in a vacuum evaporation apparatus in which lithium fluoride was set, and the chamber of it was exhausted to a pressure of 1×10⁻⁴ Pa. A lithium-fluoride film was formed to a thickness of 1 nm as controlling the temperature so that the lithium fluoride located so as to form a lithium-fluoride film all over the TFT substrate without interposing a mask between the evaporation source and the TFT substrate forms a lithium-fluoride film at a film-forming rate of 0.01 nm/second. A pixel electrode stacked on the TFT substrate in this manner was set as a metal layer of the organic EL element, and the lithium fluoride was set as an electron injection electrode.

Next, 8-hydroxyquinol aluminum complex (Alq₃) of 100 mg placed in a boat of tantalum as a light-emission material and α-NPD (N, N′-diphenyl-N-N-bis(1-naphthyl)-(1, 1′-biphenyl)-4, 4′-diamine) of 100 mg placed in a boat of tantalum as a hole transport material were separately prepared, and were set in a vacuum evaporation apparatus so that they are different evaporation sources.

The TFT substrate provided with cathodes was moved into the same vacuum evaporation apparatus without breaking the vacuum, and the boat containing the Alq₃ was heated. After the temperature was controlled until the evaporation rate of α-NPD became a constant rate of 0.3 nm/second, a shutter provided above the boat was opened to start forming a film, and at the point of time when the film was formed to a thickness of 50 nm the shutter was closed and the evaporation was ended. In the same manner, a film of α-NPD was formed to a thickness of 55 nm at a film-forming rate of 0.3 nm/second, and the formation of an organic layer was ended.

Next, the TFT substrate provided with organic layer was moved into a magnetron sputtering apparatus using IZO as a target without breaking the vacuum. And a film of IZO was formed to a thickness of 150 nm at a substrate temperature of the room temperature, at an oxygen partial pressure of 0.01 Pa and at a power of 1 W/cm².

As a result of connecting the organic EL element made in this manner to a power source and measuring the light emission of it by means of a prober apparatus in order to confirm the light emission of it, the emission of a green light with no leak current could be observed.

And a comparative example was made by a conventional method in order to confirm characteristics of the above organic EL element. A procedure for making the comparative example and its characteristics were as follows.

First, a mixture of Al and Li being ordinarily used was used as a cathode material when making an organic EL element, and a mask formed into a fine pattern was interposed between an evaporation source and a substrate so that a film was formed only on a pixel electrode when a cathode film was formed. A TFT substrate on which an organic EL element was stacked was made in the same manner as the above embodiment except that a mixture of Al and Li was used as a cathode material and a mask was interposed. As a result of connecting the organic EL element made in this manner to a power source and measuring the light emission of it by means of a prober apparatus in order to confirm the light emission of it, a leak current thought to be caused by the diffusion of lithium occurred and the light emission of it was unstable.

The present invention relates to an organic EL display device of an active matrix driving type and has the following advantages.

The first advantage is that organic EL elements of an active matrix inversely-layered type can be formed into a film on the whole surface of a substrate so as to cover commonly a plurality of pixel electrodes without forming a fine mask film, thanks to using an insulating material as an electron injection electrode of the organic EL element.

And the second advantage is that by using materials of the present invention as an electron injection electrode, it is possible to suppress the diffusion of atoms into the TFT side during or after the formation of a film and reduce erroneous operations and short circuits of the TFTs.

What is claimed is:

1. An organic electroluminescence display device comprising:
a plurality of thin-film transistors formed on a substrate,
a plurality of pixel electrodes each being electrically connected to one of the source region and drain region of each of said thin-film transistors,
an electrically insulating electron injection layer formed commonly on said plurality of pixel electrodes,
an organic layer including a light-emission layer formed on said electron injection layer, and
a hole injection layer formed on said organic layer.

2. A display device according to claim 1, wherein said electron injection layer is made of an oxide selected from an oxide of alkali metal and an oxide of alkaline-earth metal.

3. A display device according to claim 1, wherein said oxide of alkali metal is lithium oxide.

4. A display device according to claim 1, wherein said electron injection layer is made of a fluoride selected from a fluoride of alkali metal and a fluoride of alkaline-earth metal.

5. A display device according to claim 4, wherein said fluoride of alkali metal is lithium fluoride and said fluoride of alkaline-earth metal is selected from samarium fluoride and magnesium fluoride.

6. A display device according to claim 1, wherein said electron injection layer is formed to a thickness of 0.5 to 10 nm.

7. A display device according to claim 1, wherein said organic layer has an electron transport layer being in contact with said electron injection layer.

8. A display device according to claim 7, wherein said electron transport layer is made of a quinoline-based complex.
